(19) United States
(12) Patent Application Publication
(10) Pub. No.: US 2010/0157566 A1
(43) Pub. Date: Jun. 24, 2010

(54) Electronic shield assembly and methods

(76) Inventors: Robert Bogursky, Encinitas, CA (US); Kenneth Krone, San Diego, CA (US); Peter Bellantoni, San Diego, CA (US); Haim Feigenbaum, Irvine, CA (US)

Correspondence Address: GAZDZINSKI & ASSOCIATES, PC, 16644 WEST BERNARDO DRIVE, SUITE 201, SAN DIEGO, CA, 92127, US

(21) Appl. No.: 12/317,089

(22) Filed: Dec. 19, 2008

(51) Int. Cl. H05K 9/00; B05D 5/12

(52) U.S. Cl. 361/816; 427/126.1

(57) ABSTRACT

A shield assembly useful in the attenuation of electronic noise or spurious electric signals. In one embodiment, the shielding assembly comprises a metallic component that is encapsulated with an electronic component to be shielded, such as an integrated circuit. A conductive coating is applied to an exterior surface of the encapsulated metallic and electronic components so that it is in contact with the metallic component. The metallic component is formed using a selective metal deposition process (e.g., electroforming) and a laser-cutting process that increase manufacturing efficiency and provide enhanced mechanical and structural features, including especially the ability to make the shield very thin, have a high degree of co planarity, and maintain a low profile for the shielded electronic component as a whole (i.e., add very little height to that of the electronic component). Methods of manufacturing and utilizing the shielding assembly in designs are also disclosed.

### RELATED APPLICATIONS

This application is related to co-pending and co-owned U.S. patent application Ser. No. 11/899,808 filed Sep. 7, 2007 and entitled “ELECTRONIC SHIELDING APPARATUS AND METHODS”, which is incorporated herein by reference in its entirety.

### COPYRIGHT

A portion of the disclosure of this patent document contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### FIELD OF THE INVENTION

The present invention relates to the field of electrical devices and electronics, and specifically in one aspect to apparatus and methods for reducing the effects of spurious electrical signals or other “noise” on electronic components.

### DESCRIPTION OF RELATED TECHNOLOGY

In electronic devices such as e.g., computers, cellular telephones and other wireless applications, it is often necessary to shield the printed circuit board and/or other electronic components to limit or prevent emissions caused or received by such components. These “spurious” signals (typically radio frequency or electromagnetic energy of a fairly high frequency, but which may also comprise other types of energy or radiation) may result for any number of different reasons, such as exposed conductor runs, component leakage, undesired harmonics, etc. However, these emissions represent a significant source of possible interference with the operation of the components or the device at large, and hence are of significant concern. This is particularly true of small, hand-held or very thin devices which utilize very close and compact component positioning, since the source of the noise is often just that much closer to the affected component(s).

In typical prior art solutions to electronic noise mitigation or shielding, plastic casings surrounding the electronic component are typically covered with metal plating, metallized paint, or other metallic coatings, thereby in effect forming a “Faraday cage”. In other applications, metal filled plastics or elastomers are used to achieve sufficient shielding. Another commonly used method is to place a metal shield (typically a copper, steel, or other alloy) over the printed circuit board (PCB) or sections of the board containing the electronic components that emit offending signals (or which must otherwise be shielded from external signals).

Many examples of technologies that ostensibly reduce spurious electrical signals are evidenced in the prior art. For example, U.S. Pat. No. 5,151,769 to Immorlica, Jr., et al. issued on Sep. 29, 1992 and entitled “Optically patterned RF shield for an internal circuit chip for analog and/or digital operation at microwave frequencies” relates to an RF shield for an individual or a collection of internal circuit chips in a module containing a plurality of hybrid interconnected chips generating interfering RF fields that would interfere with operation of that chip if unshielded. The chips in the module may function in the analog and/or digital mode. The RF shield comprises separate metallizations under and over the chip, the two metallizations being interconnected by a line of discrete electrically conductive vias forming cage-like sides to complete an electrically conductive enclosure about the chip. The vias are spaced closely enough to prevent the escape or entry of RF waves at the frequencies of interest. The RF shield is advantageously fabricated using metallizations and vias that are optically patterned by the same process steps used to effect hybrid interconnection of the chips.

U.S. Pat. No. 5,177,856 to Rogers, et al. issued Jan. 12, 1993 and entitled “Method of making a shield for a printed circuit board” discloses a shielding assembly for a circuit board. This assembly is formed by providing a substantially flat piece of metal that is used to form a shield assembly. A template is obtained indicating locations of folds and tabs. The folds are at locations that enable the tabs to be located in the holes on the circuit board. The template is used to etch grooves and to etch tabs. This can be used to form a shielding assembly.

U.S. Pat. No. 6,319,740 to Heffner, et al. issued Nov. 20, 2001 and entitled “Multilayer protective coating for internal circuits and multi-chip modules and method of applying same” discloses a method of forming a multilayer opaque coating on an internal circuit or multi-chip module. First, an opaque coating composition is heated to a molten state and the molten opaque coating composition is applied so as to form an opaque coating that overlies active circuitry on the surface of the internal circuit or multi-chip module, to prevent optical and radiation based inspection and reverse engineering of the active circuitry. Further coatings are applied over the opaque coating to shield the active circuitry of the internal circuit or multi-chip module from the adverse affects of electromagnetic interference and/or high-energy radiation.

U.S. Pat. No. 6,621,158 to Martin, et al. issued Sep. 16, 2003 and entitled “Package for sealing an internal circuit die” discloses a die that is sealed with a cap. The seal can be hermetic or non-hermetic. If hermetic, a layer of glass or metal is formed in the surface of the die, and the cap has a layer of glass or metal at a peripheral area so that, when heated, the layers form a hermetic seal. A non-hermetic seal can be formed by bonding a cap with a patterned adhesive. The cap, which can be silicon or can be a metal paddle, is electrically coupled to a fixed voltage to shield the part of the die.

U.S. Pat. No. 6,636,406 to Anthony issued Oct. 21, 2003 and entitled “Universal multi-functional common conductive shield structure for electrical circuitry and energy conditioning” discloses a layered common conductive shield structure with conductive pathways for energy and EMI conditioning and protection that also possesses a commonly shared and centrally positioned conductive pathway or electrode of the structure that can simultaneously shield and allow smooth energy interaction between grouped and energized conductive pathway electrodes. The invention of Anthony, when energized, allows the contained conductive pathways or electrodes to operate with respect to one another harmoniously, yet in an oppositely phased or charged manner, respectively. It also provides EMI filtering and surge protection while maintaining apparent even or balanced voltage supply between a source and an energy utilizing-load when placed into a circuit and energized. The shielded structure will also be able to simultaneous and effectively provide energy conditioning functions that include bypassing, energy and signal decoupling, energy storage, continued balance in SSO (Simultaneous Switching Operations) states and all without contributing disruptive energy parasitics back into the circuit system.

U.S. Pat. No. 6,873,031 to McFadden, et al. issued Mar. 29, 2005 and entitled “Shielding device used for various components mounted on circuit board aligned with selectively cut areas” discloses a shielding device in which a layer of deformable electrically conductive material is conformed to fit over the components on the board. In one embodiment of the invention the deformable material is conductive foam, such as metallized foam. One or both sides of the foam layer can be covered with dielectric material. Portions of the dielectric material and foam can be removed, such as from the bottom layer to create insulating slants over the components. Cuts in the deformable material lead to compression only over the component. The board can be placed over the components, which are received in recesses in the shield which are either preformed or result from compression of the deformable material at the location of the components. In one embodiment of the invention, regions of conductive layer are removed and the layer is placed over the components. A top layer is placed thereover. The invention also relates to the method of foaming the board level shield.

United States Patent Publication No. 20020102835 to Stucchi, et al. published Aug. 1, 2002 and entitled “Method of fabrication and device for electromagnetic-shielding structures in a damascene-based interconnect scheme” discloses a shielded interconnect and a method of manufacturing a shielded interconnect implemented in a damascene back-end-of-line technology to form electromagnetically shielded interconnects. The standard metallization of the damascene technology is used as a core layer in a coaxial interconnect line. Prior to filling the via and trench openings in the damascene stack with this standard metallization, conductive and dielectric layers are formed as shield and insulator layers, respectively, of the coaxial interconnect line.

U.S. Pat. No. 7,135,766 to Costa, et al. issued Nov. 14, 2006 and entitled “Integrated power devices and signal isolation structure” discloses a flip chip power device having an integrated low inductance ground and heat sink path and an isolation structure. A substrate is formed having transistors and an ohmic contact region circumscribing the transistors. Dielectric layers are formed on the substrate, and a common metal layer is formed on the dielectric layers. An isolation metal layer is formed on the dielectric layers above the ohmic contact region. The common metal layer is coupled to a first region of each of the transistors, and the isolation metal layer is coupled to the ohmic contact region. A first bump is formed on the common metal layer, and a second bump is formed on the isolation metal layer. When the power device is attached to a second substrate, the first bump forms a low inductance ground and heat sink path to the second substrate, and an isolation structure is formed.

U.S. Pat. No. 7,342,303 to Berry, et al. issued Mar. 11, 2008 and entitled “Semiconductor device having RF shielding and method therefore” discloses a semiconductor device and method of manufacturing that has a substrate having a plurality of metal layers. At least one metal layer is exposed on at least one side surface of the semiconductor device. A die is coupled to the substrate. A mold compound encapsulates the die and a top surface of the substrate. A conductive coating is applied to the mold compound and to at least one metal layer exposed on at least one side surface of the substrate.

United States Patent Publication No. 20020109218 to Akram, published Aug. 15, 2002 and entitled “Method and apparatus for packaging flip chip bare die on printed circuit boards” discloses an apparatus and a method for providing a fully protective package for a flip chip with a protective shield plate and an under fill encapsulant material. The apparatus comprises a semiconductor chip electrically connected by flip chip attachment to a substrate. A shield plate is placed in contact with a back surface of the semiconductor chip. An under fill encapsulant is disposed between the semiconductor chip and the shield plate, and the substrate. A globe top encapsulant may be applied about the periphery of the upper surface of the shield plate that extends to the substrate for additional protection and/or adherence.

United States Patent Publication No. 20030002271 to Nurminen, published Jan. 2, 2003 and entitled “Internal EMC shield for internal circuits and multiple chip modules” discloses a semiconductor package that has a die connected to a substrate with a transfer molding applied over the die. The transfer molding includes an electrically conductive material for forming an electromagnetic compatibility shield as an integral part thereof.

Despite the broad variety of techniques described above, each suffers from one or more disabilities including inter alia: (i) substantial difficulty in encapsulating the shielded device(s); and (ii) limitations with regards to the need for smaller and lower profile shielded devices. Prior art shield solutions exist (see e.g., U.S. Pat. No. 7,342,303 to Berry, et al. discussed above), but these generally suffer from having too high a profile. Moreover, these solutions are coating-based, are subject to environmental factors, and do not accommodate discontinuities in shapes well.

Based on the foregoing, there is a salient need for improved shielding apparatus and methods that both minimize the space required (especially height) to provide the necessary level of shielding, and which are very cost effective and robust.

In addition, it would be desirable to have a shielding solution that is disposed on the electrically active chips within an electronic component (e.g. an MCM component) or other devices requiring shielding, thereby eliminating the need for the device manufacturer (such as e.g., a cellular phone manufacturer or other miniature electronics or device or component producer) to explicitly consider shielding the design and construction of their product.

Such an improved shielding solution would also ideally substantially maintain the electronic components' existing low vertical profile (i.e., height), and not significantly increase the effective size or footprint of the electronic component to be shielded.

### SUMMARY OF THE INVENTION

In a first aspect of the invention, a shielding assembly is disclosed. In one embodiment, the assembly comprises: a top wall comprising an over-molded polymer with a conductive coating applied thereto; and a side wall disposed substantially around at least a portion of the periphery of the top wall. The shielding assembly further comprises a metallic structure that has been formed at least in part using a metal deposition process, and subsequently at least partially encapsulated by the over-molded polymer, the conductive coating being in contact with at least a portion of the metallic structure.

In one variant, the metal deposition process comprises an electroforming process, and the thickness of the side wall and the plurality of standoff features is less than or equal to 0.10 mm.

In another variant, the metal deposition process comprises an electroforming process, and the thickness of the top wall is less than or equal to 0.10 mm.

In yet another variant, the metallic structure further comprises at least one encapsulant fill aperture, formed e.g., within at least a top surface of the metallic structure.

In a second aspect of the invention, a shielding assembly useful in the attenuation of electronic signals is disclosed. In one embodiment, the assembly comprises: a metallic structure comprising: a plurality of side walls; and a plurality of standoff features; a non-conductive polymer body comprising a top surface and at least partly encapsulating the metallic structure; and a conductive coating disposed on the top surface, the conductive coating electrically coupled to at least a portion of the metallic structure.

In one variant, the metallic structure is formed using an electroforming process, and wherein the thickness of the plurality of side walls and the plurality of standoff features is less than or equal to 0.10 mm.

In another variant, the metallic structure further comprises at least one fill aperture formed at least in a top surface of the metallic structure.

In a further variant, the shield assembly is adapted to at least partly receive two or more discrete electronic devices, and further comprises a substrate, the two or more discrete electronic devices and metallic structure coupled to the substrate. The conductive coating is electrically coupled to the substrate via the metallic structure.

In a third aspect of the invention, a shielding apparatus for attenuating electronic signals or noise is disclosed. In one embodiment, the apparatus comprises: a top wall comprising a fill aperture; and at least one side wall. The shielding apparatus comprises an electroformed metallic structure, with a plurality of features produced using a process comprising laser-cutting of at least portions of the structure.

In one variant, the thickness of at least one of the top wall and the at least one sidewall is less than or equal to 0.10 mm, and the top wall comprises a co-planarity which varies less than or equal to 0.10 mm.

In another variant, the top wall further comprises at least one structure which projects into the aperture, the at least one structure used for making electrical contact with a conductive layer.

In a fourth aspect, a method of manufacturing a shield assembly is disclosed. In one embodiment, the shield assembly comprises a shield apparatus, a top wall, and a sidewall disposed substantially about at least a portion of the periphery of the top wall, and the method comprises: providing a mandrel; depositing, using a metal deposition process, at least a portion of the shield apparatus on areas of the mandrel; and laser-cutting at least a portion of the shield apparatus.

In one variant, the method further comprises placing the shield assembly in a carrier.

In another variant, the shield assembly is part of an array of shield assemblies, and the act of depositing comprises electroforming each shield apparatus of the array of shield assemblies substantially simultaneously.

In yet another variant, the method further comprises encapsulating at least a portion of the shield apparatus to form at least a portion of the top wall and sidewall, and cutting at least a portion of the encapsulated shield assembly, thereby exposing at least a portion of the shield apparatus. A conductive layer is deposited on the top wall, the conductive layer contacting with the exposed portion of the shield apparatus.

In a fifth aspect of the invention, a shielded electronic assembly is disclosed. In one embodiment, the assembly comprises: a substrate; at least one electronic component disposed directly or indirectly on the substrate; a substantially metallic electroformed shield component substantially surrounding the at least one electronic component, the shield component being in electrical contact with at least one conductive area on the substrate; an encapsulant substantially covering at least portions of the at least one electronic component and the shield component; and a conductive layer disposed atop at least a portion of the encapsulant, the conductive layer being in electrical contact with the shield component.

In one variant, the at least one electronic component comprises at least one integrated circuit (IC).

In another variant, the shield component comprises a sidewall portion having a plurality of standoffs, and a top portion having an aperture formed therein.

In yet another variant, at least portions of the shield component are less than or equal to 0.05 mm thick.

In a sixth aspect of the invention, a shield component useful in shielding electronic noise is disclosed. In one embodiment, the component comprises a top wall and a sidewall disposed substantially about at least a portion of the periphery of the top wall, and the component is manufactured according to the method comprising: depositing, using a wet metal deposition process, one or more layers of a shield material on areas of the mandrel to form the shield component; and laser-cutting at least a portion of the shield component; wherein at least portions of the shield component are less than or equal to 0.05 mm thick.

In a seventh aspect of the invention, a low-profile shielded electronic assembly is disclosed. In one embodiment, the assembly comprises: a substrate; at least one electronic component disposed directly or indirectly on the substrate; a substantially metallic electroformed shield component substantially surrounding the at least one electronic component, the shield component being in electrical contact with at least one conductive area on the substrate; an encapsulant substantially covering at least portions of the at least one electronic component and the shield component; and a conductive layer disposed atop at least a portion of the encapsulant, the conductive layer being in electrical contact with the shield component. The conductive layer and the encapsulant are the only components disposed over the majority of the top surface area of the at least one electronic component.

In an eighth aspect of the invention, a method of designing a shielded electronic device is disclosed. In one embodiment, the method comprises: including at least one electronic component within the design; locally shielding the at least one electronic component, the local shielding comprising disposing a substantially adherent shield assembly comprised of an electroformed shield component and a conductive layer in communication therewith substantially about the at least one electronic component; and not including additional shielding relating to the at least one component elsewhere within the design of the device.

In a ninth aspect, a method of forming a shielded component assembly is disclosed. In one embodiment, this method comprises a technique that is not subject to environmental factors or discontinuities in shapes. An adjustable “mesh top” approach is utilized (i.e., wherein the size of the mesh used can be varied), which provides increased contact area and larger openings, thereby ultimately saving on vertical height of the assembly as a whole. All metallization is advantageously placed on the top of the assembly where it is accessible. Moreover, the exemplary assembly formed using this method can be fabricated in an array, and subsequently separated directly (e.g., using a dicing saw), versus prior art techniques (which require dicing to expose the sides and ground layer(s), then protection of the bottom of the assembly, then metallization, etc.) which are more laborious and require additional processing steps.

Other features and advantages of the present invention will immediately be recognized by persons of ordinary skill in the art with reference to the attached drawings and detailed description of exemplary embodiments as given below.

### BRIEF DESCRIPTION OF THE DRAWINGS

The features, objectives, and advantages of the invention will become more apparent from the detailed description set forth below when taken in conjunction with the drawings, wherein:

FIG. 1 illustrates a perspective view of an exemplary low-profile electromagnetic shield assembly array manufactured in accordance with the principles of the present invention.

FIG. 1A illustrates a perspective view of an exemplary internal shield structure utilized within the shield assembly illustrated in FIG. 1.

FIG. 1B illustrates a perspective view of the exemplary internal shield structure of FIG. 1A mounted on a substrate comprising a plurality of electronic components.

FIG. 1C illustrates a perspective view of a second exemplary internal shield structure adapted for automated placement manufactured in accordance with the principles of the present invention.

FIG. 1D illustrates a cross sectional view of the exemplary internal shield structure mounted on a substrate of FIG. 1B.

FIG. 2 illustrates a 1×4 array of an exemplary low-profile electromagnetic shield assembly array manufactured in accordance with the principles of the present invention.

FIG. 2A illustrates a 6×4 low-profile electromagnetic shield assembly array manufactured in accordance with the principles of the present invention.

FIG. 2B illustrates a detailed view of a dicing saw cut channel of the exemplary low-profile electromagnetic shield assembly array shown in FIG. 2A.

FIG. 2C illustrates a cross sectional view of the exemplary low-profile electromagnetic shield assembly array shown in FIG. 2A.

FIG. 3 illustrates a perspective view of a third exemplary internal shield structure adapted for obviating dicing saw operations necessary to expose the encapsulated internal shield structure manufactured in accordance with the principles of the present invention.

FIG. 4 illustrates an exemplary manufacturing process for the exemplary low-profile electromagnetic shield assembly array of FIG. 1 in accordance with the principles of the present invention.

FIG. 5 is a perspective view of a carrier tape adapted to house the integrated shield assembly of FIG. 1.

### DETAILED DESCRIPTION OF THE PREFERRED EMBODIMENT

Reference is now made to the drawings wherein like numerals refer to like parts throughout.

As used herein, the terms “electrical component” and “electronic component” are used interchangeably and refer to components adapted to provide some electrical or electronic function such as, for example, signal conditioning, including without limitation inductive reactors (“choke coils”), transformers, filters, gapped core toroids, inductors (coupled or otherwise), capacitors, resistors, operational amplifiers, and diodes, and integrated circuits, whether discrete components or in a unitary form, whether alone or in combination.

As used herein, the term “signal conditioning” or “conditioning” shall be understood to include, but not be limited to, signal voltage transformation, blocking, filtering, current limiting, sampling, processing, and time delay.

As used herein, the term “integrated circuit (IC)” refers to without limitation any type of device, whether single or multiple die, having any level of integration (including without limitation ULSI, VLSI, and LSI) and irrespective of process or base materials (including, without limitation Si, SiGe, CMOS and GaAs). ICs may include, for example, memory devices (e.g., DRAM, SRAM, DDRAM, EEPROM/Flash, ROM), digital processors, SoC devices, FPGAs, ASICs, ADCs, DACs, radio frequency or other transceivers, memory controllers, and other devices, as well as any combinations thereof.

As used herein, the term “memory” includes any type of internal circuit or other storage device adapted for storing digital data including, without limitation, ROM. PROM, EEPROM, DRAM, SDRAM, DDR/2 SDRAM, EDO/FPMS, RLDRAM, SRAM, “flash” memory (e.g., NAND/NOR), and PSRAM.

As used herein, the terms “microprocessor” and “digital processor” are meant generally to include all types of digital processing devices including, without limitation, digital signal processors (DSPs), reduced instruction set computers (RISC), general-purpose (CISC) processors, microprocessors, gate arrays (e.g., FPGAs), PLDs, reconfigurable compute fabrics (RCFs), array processors, secure microprocessors, and application-specific internal circuits (ASICs). Such digital processors may be contained on a single unitary IC die, or distributed across multiple components.

As used herein, the term “Multi-Chip Module” or “MCM” includes without limitation any type of integrated apparatus or device of any function which includes two or more electronic devices or integrated circuits that are subsequently combined, joined or related so as to form a substantially unitary physical or electrical package.

As used herein, the term “wireless” means any wireless signal, data, communication, or other interface including without limitation WiFi (IEEE Std. 802.11), Bluetooth, 3G (3GPP, 3GPP2, UMTS), HSDPA/HSUPA, TDMA, CDMA (e.g., IS-95A, WCDMA, etc.), FHSS, DSSS, GSM, PAN (IEEE Std. 802.15), WiMAX (IEEE Std. 802.16), MWBA (IEEE Std. 802.20), narrowband/FDMA, OFDM, PCS/DCS, analog cellular, CDPD, satellite systems, millimeter wave or microwave systems, acoustic, and infrared (i.e., IrDA).

### Overview

In one salient aspect, the present invention discloses a shielding apparatus useful in the attenuation of electronic noise or spurious electric signals, such as for example those encountered within a wireless or computerized device. In one embodiment, the shielding apparatus is encapsulated with an electronic component such as an integrated circuit. At least parts of the apparatus are formed using a precise and selective metal deposition process such as electroforming in combination with a laser cutting technology that increases manufacturing efficiency and provides enhanced mechanical and structural features as well as reduced cost. The exemplary deposition process allows for inter alia planarity thickness values and precision dimensional controls that are otherwise unachievable using prior art stamping, casting or molding processes. The device is subsequently subjected to a dicing saw operation that exposes the encapsulated internal shield, which subsequently can be electrically connected with a conductive coating applied to the top surface of the device. This manufacturing process makes possible an ultra-low profile and smaller size for the shielded electronic components. For example, one embodiment of the apparatus eliminates approximately 0.15 mm of vertical height associated with structures disposed above and below the shield that is present in prior art approaches. This is a significant savings in vertical profile.

In another embodiment, an array of multiple individual shields of the same or different design is used, so as to permit simultaneous forming and processing, thereby further increasing manufacturing efficiency.

Multi-chip module (MCM) embodiments are also disclosed, wherein the shield of the invention can be applied to such modules while preserving all of the aforementioned attributes.

Methods of manufacturing and utilizing the shielding apparatus within electronic component designs are also disclosed.

### Detailed Description of Exemplary Embodiments

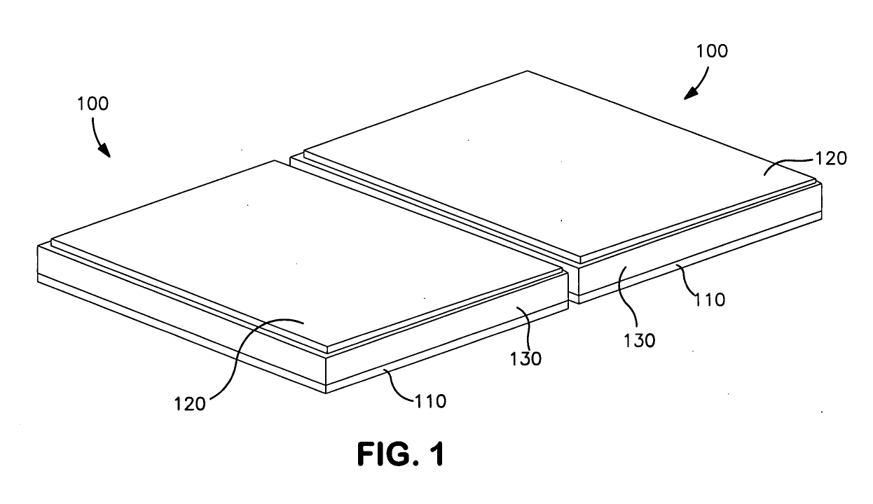

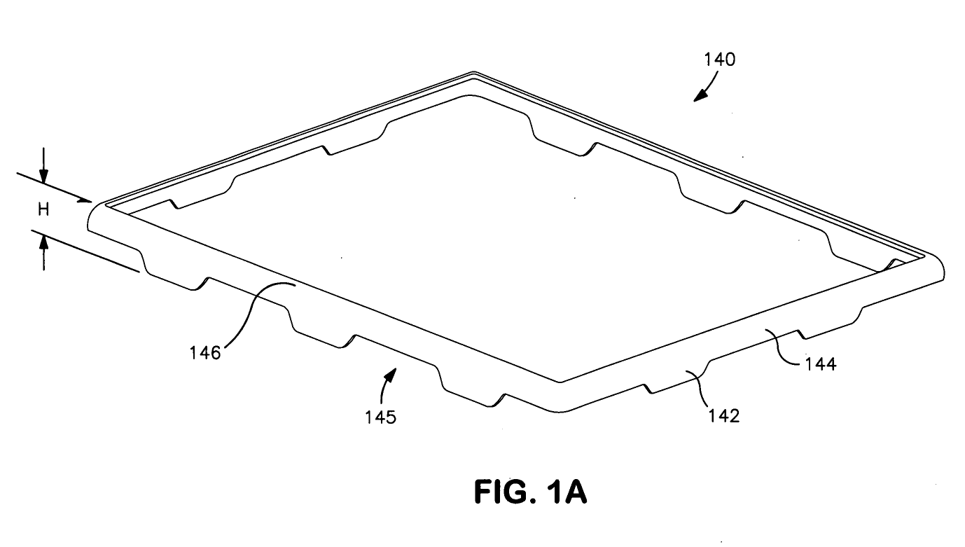

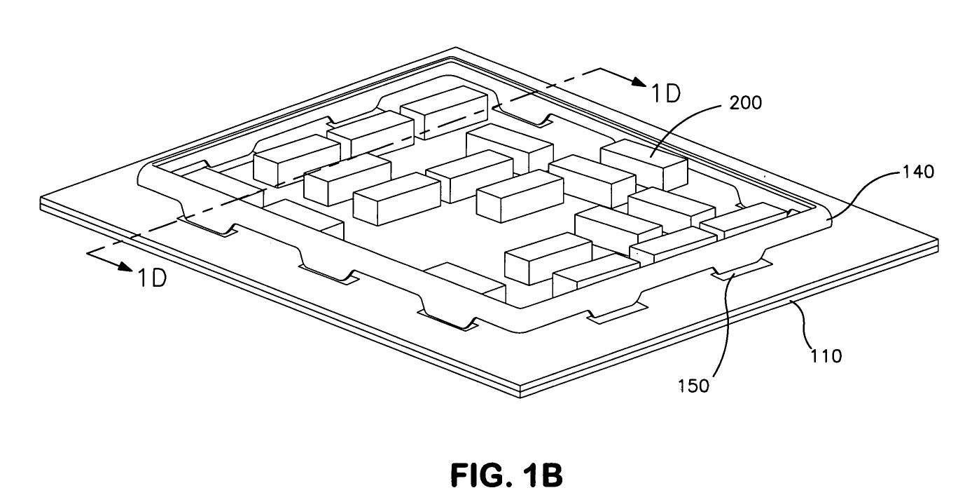

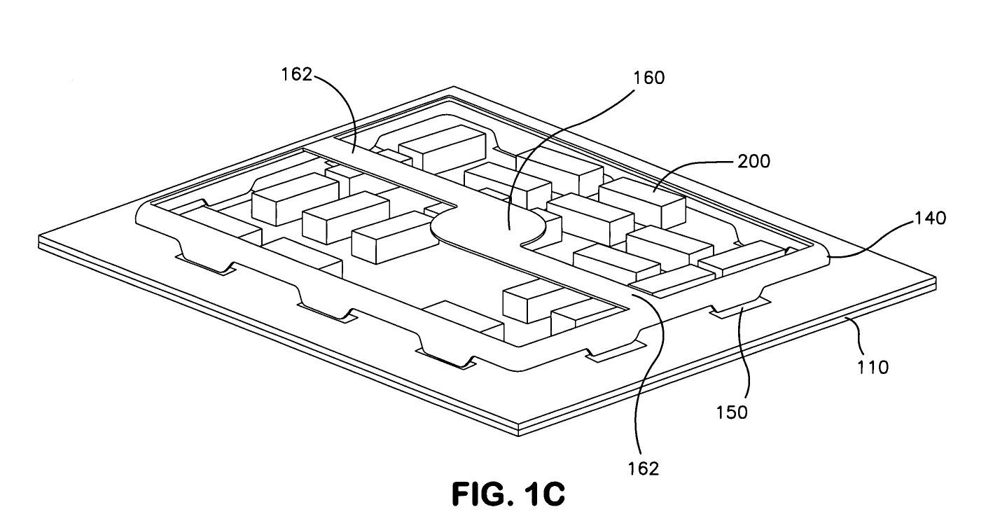

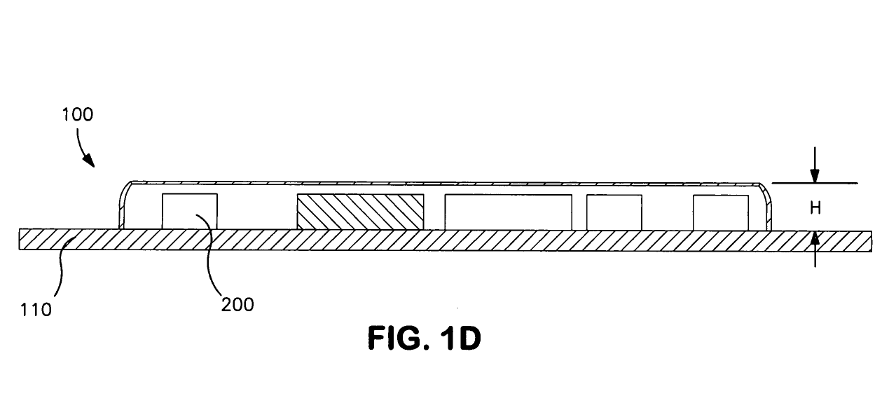

Referring now to FIGS. 1-5, exemplary embodiments of the shield apparatus (and its carrier) and methods of manufacturing are described in detail. It will be appreciated that while these embodiments are described in the context of an exemplary “flat” low-profile and rectangular or square integrated circuit (IC) application, the invention may be readily applied to other types of devices which may or may not have such features (e.g., that may be of different heights, shapes, planarities, etc.). For instance, a multi-level shield arrangement could be employed, or the shape of the shield may not be planar but rather bowed inward or outward. Moreover, the shield structure could be made round, oval, hexagonal, and so forth. Herein lies a significant advantage of the exemplary shield formation techniques of the invention; i.e., that any number of different complex shapes and varying sizes/geometries can be readily accommodated, and at low cost.

### Exemplary Mechanical Configuration

Referring to FIG. 1, a first embodiment of a low-profile electromagnetic shield assembly 100 is illustrated. The low-profile shield assembly 100 is designed particularly so as to overcome deficiencies present in prior art designs. Specifically, the shield assembly 100 comprises an open-top internal shield 140 (FIG. 1A), an over-molded non-conductive body 130 and a conductive coating 120 all disposed on an external substrate 110. The shield assembly is constructed with the open-top internal shield 140 so as to permit the shield assembly to fully accommodate the height of the encapsulated electronic components (FIG. 1D) while maintaining the lowest possible profile. In addition, the open-top internal shield facilitates the over molding process associated with the over-molded non-conductive body, and the conductive coating 120 offers a thinner alternative to a closed-top internal shield while also providing effective grounding via its connection to the internal shield 140. These and other advantages are discussed in greater detail subsequently herein.

Referring now to FIG. 1A, in an exemplary embodiment, the internal shield structure 140 comprises an electroformed copper or nickel-based alloy or combination structure suitable for attenuating spurious electromagnetic or other noise or undesired signals. The exemplary electroforming process comprises a process of precision metal part fabrication which uses electro-deposition in a plating bath over a precise base form or “mandrel” to which the subsequently formed or shaped part is then removed. In effect, the internal shield structure 140 is synthesized by controlling the electro-deposition of metal passing through an electrolytic solution onto the mandrel form. The process is essentially very similar to electroplating well known in the electronic arts; however, the process differs from electroplating in that the skin of electroplated material is much thicker and advantageously can exist as a self-supporting structure once the mandrel is removed.

The electroforming process has many advantages when utilized in applications such as shielding in electronic components, as the electroforming process is capable of faithfully reproducing the form of the mandrel more accurately (with lower tooling cost and faster tooling lead times) than other metal forming techniques such as casting, stamping or drawing. Further, the shape possibilities for the shield structure are virtually unlimited in that complex curves, cavity dividers, legs or stanchions, standoff locations, or other structures can be readily incorporated without the limitations associated with stamping and/or other common manufacturing processes.

Electroforming also has distinct advantages over metal stamping processes in that there are no resultant seams in the formed part (e.g., shield) which improve its strength and attenuation performance. Further, co-planarity of the structure 140 is excellent when using the electroforming process, and such co planarity can be maintained well within the industry standard (e.g., 0.1 mm) associated with standard mounting processes since warpage and distortion are virtually non-existent in electroformed parts.

Stampings also tend to have limits associated with them in terms of wall height, thickness, etc. There are also issues presented with stampings relating to bend radius limitations (e.g., for forming sidewalls). Electroforming accordingly provides added flexibility when designing structures to minimize the amount of space consumed in the ultimate shielding application. Further, the tooling associated with electroforming processes is often comparatively simple (as compared with e.g., a prior art progressive die approach), thereby permitting the manufacture of new shield structure designs in a matter of days or weeks as compared with progressive stamping tooling which often can take on the order of months to prepare.

In addition, since the mandrel used in electroforming is often machined or otherwise formed as an outside surface (or inside inserts), close dimensional tolerances and high surface finishes can be held (via electrical discharge machining or “EDM” and the like) and maintained on complex interior configurations. The electroforming process allows high-quality duplication of the master, and therefore permits very high quality and tolerance production, at relatively low unit costs with excellent part-to-part repeatability.

Casting or molding techniques characteristically have difficulty making long thin sections flat (planar), and hence necessarily produce a thicker (less spatially efficient) and less effective shield.

It will be recognized however that while electroforming comprises an excellent choice, other manufacturing processes such as casting, forming and the like may readily be used consistent with the present invention, such as where the particular attributes of electroforming are not required. The electroforming process is exemplary in applications where, for example, the complexity of the shape, the high precision required and/or the relatively small size of the manufactured component are necessary requirements unachievable with other technologies. However, all such alternative build processes are contemplated for use with the present invention where the application permits.

In addition to the aforementioned electroforming, additional features are preferably manufactured into the electroformed shields using laser cutting technology. Laser cutting technology has advantages in terms of cost and manufacturability over other techniques for producing features such as the open-top 146 and standoffs 142 (FIG. 1A). Techniques such as selective non-conductive masking during the electroforming process can result in yield-related issues associated with removing the part from the mandrel. Accordingly, laser cutting may be utilized to reduce these yield issues, especially where the geometry of the device could otherwise be problematic to a given manufacturing process.

As the name implies, laser cutting is a technology that uses laser energy (coherent electromagnetic radiation) to cut the underlying base material. Laser cutting works by directing the output of a high power laser, typically controlled via computer, at the material to be cut. The base material then either melts, burns, vaporizes, or is blown away by a jet of gas, leaving a laser cut edge with a high quality surface finish. So-called 6-axis lasers can perform cutting operations on parts that have been pre-formed by, inter alia, the electroforming process described above. These lasers are either controlled by moving the laser beam itself, or alternatively by placing the device to be worked on a high-speed table while the laser head and beam remain fixed.

Advantages of laser cutting include a lack of physical contact on the piece to be cut (since there is no cutting edge which can become contaminated by the material or conversely which can contaminate the material), and repeatability, as there is no wear on the laser. In applications where the material to be cut is thin, such as the aforementioned described internal shield of FIG. 1A, there is also a reduced chance of warping the base material that is being cut, as laser systems typically have a relatively small heat-affected zone as compared with other cutting techniques and systems. In one exemplary embodiment, the laser technology utilized comprises a fiber laser of the type known to those of ordinary skill in the industrial laser arts.

In an alternative embodiment, the internal shield structure 140 may be manufactured using chemical subtraction process or electrochemical etching (i.e. utilizing photo-lithography, chemical milling, etc.) processes of the type well known in the art. Chemical etching processes typically have advantages in terms of prototype cost and lead times, as the tooling charges associated with the process (e.g. photo-resist masks or templates) tend to be minimal. The resultant etched shield structure may then subsequently be plated using standard methods. For example, in one variant, the shield or other component is electroformed, and then features or parts are etched therein (or vice-versa).

In the case of photo-resists, it will be appreciated that either a positive resist or negative resist (or combinations thereof, e.g., as part of different process steps) may be utilized consistent with the invention. As is well known, positive and negative resists are effectively mirror images of one another, and allow either for the removal of all resist surrounding the exposed portions of the resist, or only the exposed portions, respectively. These capabilities can be used to, e.g., build legs, sidewalls, etc., or for any number of other purposes.

In yet another embodiment, the shield structure may be formed using a multi-component approach, such as via electroforming the shield over a polymer or even another metal disposed over the mandrel. In one variant, a layer of plastic is formed over the mandrel (such as via deposition, molding, or other suitable process). Alternatively, the plastic component may be pre-molded and then placed over the mandrel. Next, at least a portion of the plastic is used as the basis for electroforming or “metallizing”. Once the electroform process is complete, the mandrel may be removed, leaving the metallized plastic. Similarly, the plastic may be replaced with other materials, such as e.g., metals, or even composites. In one variant, the metal is chosen to be dissimilar (i.e., not the same as the electroformed metal layer). In another variant, the metals are selected to be substantially identical. See also the methods and apparatus disclosed in U.S. Pat. No. 6,294,729 to Kaplo issued Sep. 25, 2001 and entitled “Clad polymer EMI shield”, which is incorporated by reference herein in its entirety, which may be used consistent with the invention.

It will be appreciated that literally any removable selective metallization/deposition process (i.e., a process wherein metal is built up or deposited on selective regions of a mandrel or other such structure, from which it may then be removed) may be used to form all or parts of the internal shield element(s) described herein. For example, in addition to electroforming described previously herein, other such processes may include without limitation chemical vapor deposition (CVD), vacuum metallization, vacuum deposition, etc., which are well known in the processing arts. These processes each advantageously allow precise control of metallization layer thickness and selective deposition (e.g., are amenable to use of masking techniques). Still other approaches and configuration can be used consistent with the present invention; see e.g., U.S. Pat. No. 6,768,654 to Arnold, et al. issued Jul. 27, 2004 and entitled “Multi-layered structures and methods for manufacturing the multi-layered structures”, U.S. Pat. No. 6,833,031 to Arnold issued Dec. 21, 2004 entitled “Method and device for coating a substrate”, U.S. Pat. No. 6,909,615 to Arnold, et al. issued Jun. 21, 2005 entitled “Equipment and methods for producing continuous metallized thermoformable EMI shielding material”, U.S. Pat. No. 7,109,410 to Arnold, et al. issued Sep. 19, 2006 entitled “EMI shielding for electronic component packaging”, and U.S. Pat. No. 7,129,422 to Arnold issued Oct. 31, 2006 entitled “EMI absorbing shielding for a printed circuit board”, each of the foregoing being incorporated herein by reference in its entirety.

Referring again to FIG. 1A, the internal shield structure 140 comprises several noteworthy features. Firstly, the sidewall structures 144 can be made quite thin, while at the same time remaining a self-supporting structure. In one embodiment, the thickness of the wall structure is made to have a thickness of approximately 0.05 mm (roughly 0.002 in.), although it will be recognized that other thicknesses (and even varying thicknesses as a function of location) can be used with equal success.

Moreover, a “rigidizing” flange can be added to the sidewall structure, as can an “I beam” stress ridge (not shown).

The exemplary internal shield structure also further optionally comprises features that facilitate application of the structure such that it is encapsulated with the electronic component(s) that it is intended to shield. Specifically, the open-top construction 146 as well as the standoffs 142 provides structure which facilitates the encapsulation process, more fully described below. The size and number of the standoffs may be varied in order to balance or otherwise control the flow of encapsulant (or a comparable substance) in later optional processes, while also providing the requisite degree of electromagnetic noise attenuation. As can be expected, the larger the fill aperture and standoff, the easier it will be to flow encapsulating compounds (such as epoxy or silicone compounds) of a given viscosity around the shield structure and the electronic component(s).

The fill apertures 145 created by the standoffs and open-top construction also function to allow air and gas to escape during filling, thereby advantageously reducing voids or cavities within the filled device.

In another variant, an open-top “mesh” (e.g., cross-hatch or screen of filaments or fibers) can be used to fulfill the foregoing functions. Advantageously, the mesh size can be varied as needed (e.g., based on material properties such as viscosity, etc.) so as to provide an optimal process, while maintaining an extremely efficient use of vertical space (vertical profile conservation). This approach also enhances the contact area for any applied coatings or materials.

As previously mentioned, the overall height H of the exemplary internal shield structure is also advantageously very low. FIGS. 1A and 1D illustrate the low-profile nature of the shield structure 140 of the assembly 100. In the embodiment shown in FIG. 1A, the overall height H of the structure including its standoffs is less than 0.60 mm in height, although other embodiments with larger heights (or even varying heights) are possible. In fact, a wide variety of geometries and sizes are envisioned consistent with the invention. The possibilities and different configurations are literally boundless. It will also be appreciated that any size and units of scale can be employed within plating or forming capabilities; e.g., 4 mm×6 mm, 40 mm×60 mm, etc., the foregoing being merely exemplary.

In one variant, a nickel or nickel alloy is utilized to form the shield. Copper is selected in another variant. In yet another variant, a plurality of layers of the shield structure are formed each using different metals. It will also be appreciated that use of a magnetic material will afford the ability to remove the electroformed shield from the mandrel using a magnet. For example, in one embodiment, the magnet's shape is adapted to substantially conform to the general shape and/or size of the shield component to be removed from the mandrel and also to package the removed part.

Another salient feature of the electroformed internal shield structure of FIG. 1A is its inherent resistance to high temperatures (e.g. 260° C.) encountered in solder reflow operations ubiquitous in the electronics industry. This high-temperature capability allows a wide range of other processes such as reflow to be conducted with no deleterious effects on the shield, such as warpage or loss of strength. Moreover, the underlying base material of the structure can further be electroplated, with copper in one variant, to improve e.g. EMI shielding effectiveness, conductivity, solder ability, etc.

As can also be seen in FIG. 1A, the edges of the standoffs 142 of the shield 140 advantageously comprise rounded edges, thereby facilitating their removal from the mandrel during the exemplary electroforming process. The mandrel can either be a reusable mandrel, or alternatively may comprise a mandrel that is subsequently discarded (e.g., disposable or limited re-use). For example, the non-reusable mandrel could be chemically removed from the electroformed product if desired.

As can be seen in FIG. 1B, the standoffs 142 of the shield 140 further are adapted to connect to respective ground connections or pads 150 on the substrate 110. This provides a path to ground for the shield so that it may effectively shield the electronic components 200 contained within.

FIG. 1C illustrates an alternative embodiment whereby a portion of the shield 140 is provided into the open-top portion of the shield. This portion comprises a pick-and-place surface or pad 160 connected to the side walls of the shield via two arms 162. This feature permits the automatic placement (e.g. with a standard pick-and-place nozzle) of the shield onto the substrate 110 prior to termination of the shield to the ground pads 150 located on the substrate. While the embodiment shown illustrates a pick-and-place surface with two (2) arms, it is recognized that other configurations are possible. Such configurations can also be adapted so as to be routed over lower profile electronic components 200 so as to minimize the overall height of the shield structure 140, although this is not a requirement.

Referring now to FIG. 1D, a cross section view of the shield structure is illustrated after the electronic component 200 it shields has been encapsulated using an epoxy compound. As can be seen in FIG. 1D, both the electronic component(s) and shield structure are secured to a substrate. The substrate may comprise any number of well known materials, with BT Resin being exemplary in applications such as MCM shielding, etc. As is well known, BT Resin (such as that offered by Mitsubishi Corporation) is a high heat resistant thermosetting resin of the additional polymerization type with two main components; i.e., B (Bismaleimide) and T (Triazine Resin).

A circuit board (e.g., FR-4, epoxy glass or ceramic) may also be used.

These components are, in one embodiment, secured to the substrate using a conductive adhesive or epoxy. In another embodiment, the electronic component and shield are secured using a conductive adhesive or solder process of the type ubiquitous in the electronic arts. The clearance between the electronic component and the shield structure facilitates the flow of epoxy through the holes and the standoff gap. After encapsulation, the internal shield has become embedded with the electronic component, thereby forming a unitary electronic component assembly with internal shielding.

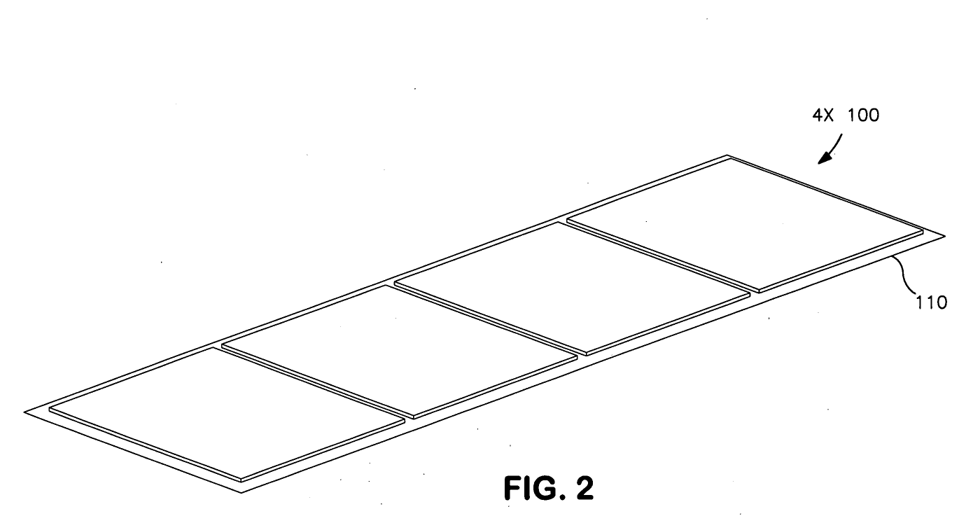

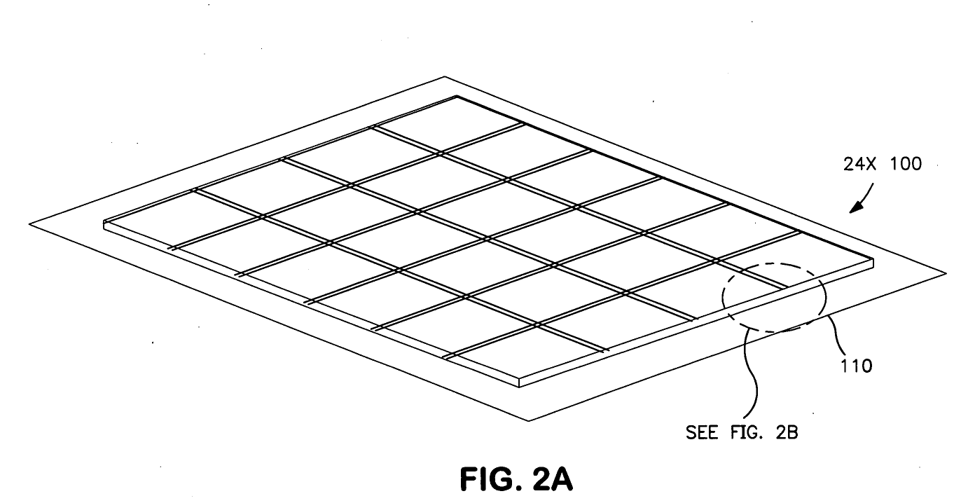

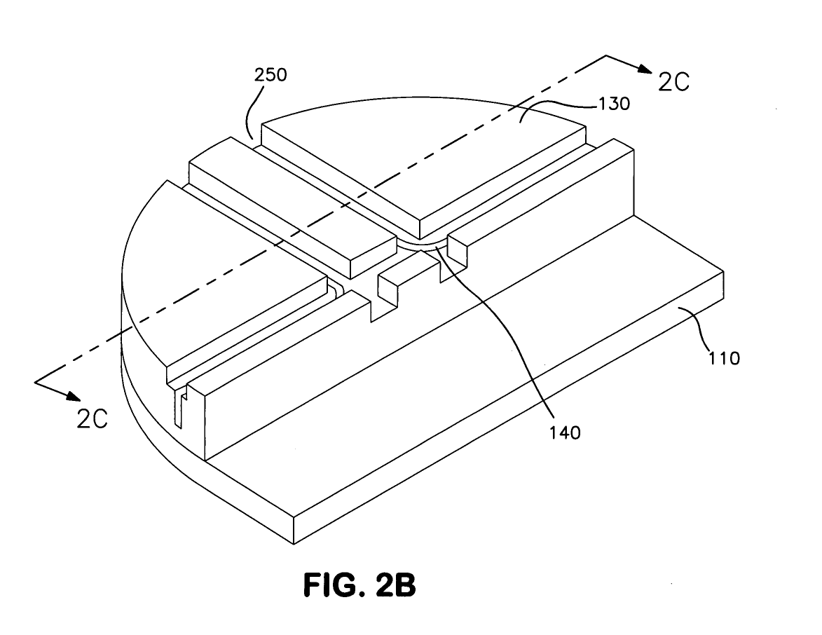

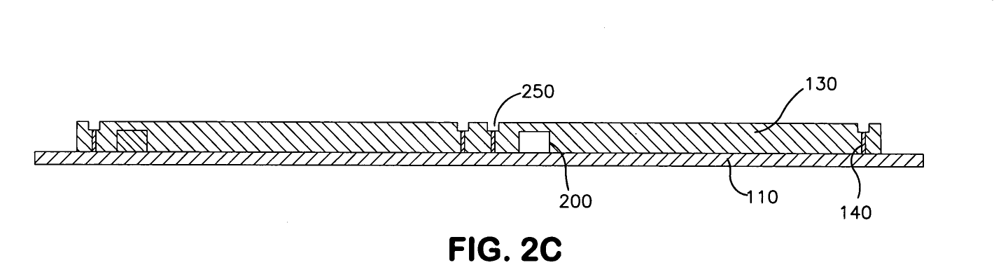

Referring now to FIG. 2, an array of shield assemblies 100 are shown and described in detail. As used herein, the term “array” refers broadly to any aggregation of shields which may or may not be the same, and may or may not be coupled or in communication with one another, and is not in any way limited to a traditional “row and column” array configuration. In the embodiment shown, the array comprises a 1×4 array. The array of FIG. 2 offers advantages in terms of high volume production such as: (1) lower product cost; (2) lower packaging cost; (3) lower per unit tooling cost; while at the same time (4) providing an opportunity to mass encapsulate (and/or separate) a plurality of electronic components. It is appreciated that while a 1×4 array is shown in FIG. 2, any number of other variations are possible (e.g. 1×3, 2×3, 3×3, etc., as well as non-row/column approaches as previously described). For instance, FIG. 2A illustrates a sheet comprising a 6×4 array of shield assemblies 100 resident on a substrate 110. FIG. 2C is a side view of the array of FIG. 2A.

Referring now to FIG. 2B, a detailed view illustrating the shield assemblies 100 prior to the application of a conductive coating is illustrated. Specifically, FIG. 2B illustrates cuts 250 placed into the non-conductive over-molding 130, thereby exposing the edges of the internal shield 140. The cuts (i.e. channels) 250 are, in one exemplary embodiment, formed using a dicing saw of the type ubiquitous in the arts. A dicing saw typically employs a high-speed spindle fitted with a diamond or other type of blade to dice, cut, or groove semiconductor wafers, silicon, glass, ceramic, crystal, and the like. Typically, dicing saws are utilized in applications where the size of the channel to be cut is relatively small (e.g. on the order of a few thousandths of an inch). Accordingly, the use of a dicing saw to form the channels 250 shown in FIG. 2B may readily be substituted with alternative processes suitable for the desired dimensions.

As previously discussed, the internal shield structure 140 is connected to the substrate 110 ground via the use of conductive adhesives, soldering, or the like. In addition, as was previously discussed, the non-conductive over-molding 130 of the illustrated embodiment does not act to mitigate spurious electromagnetic emissions to and from the device 100. Accordingly, a conductive coating (as illustrated in FIG. 1) is applied to the top portions of the over-molding so as to provide the device 100 with effective shielding. A salient advantage of the present embodiment is the aforementioned channel forming process which exposes the internal shield structure 140. With the shield 140 exposed as shown best in FIG. 2B, the conductive coating applied to the device assembly can be grounded directly to the substrate 110 via the shield 140. This approach is also more reliable than coating the edge of a cut PCB/trace.

The conductive coating 120 illustrated in FIG. 1 may comprise any number of suitable materials including conductive adhesives, conductive epoxies, conductive ink and the like. In an exemplary implementation, a silver or copper-filled epoxy or paint is selected. It will be appreciated that the material chosen should take into account coating thickness and EMI performance among other considered factors. The application of conductive coatings is well understood by one of ordinary skill in the art, and accordingly is not discussed further herein.

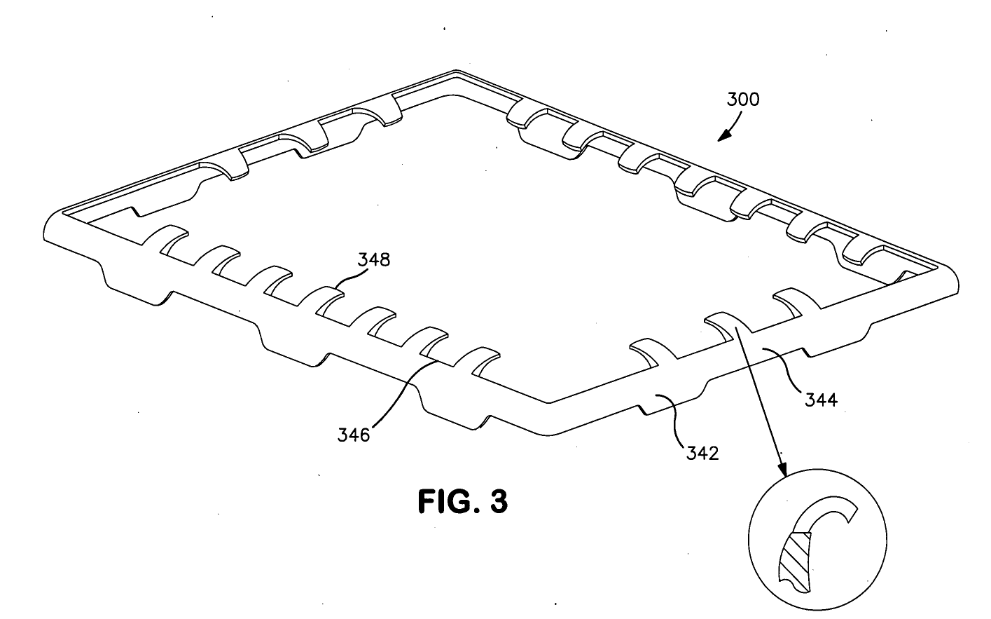

Referring now to FIG. 3, an alternative embodiment of an internal shield structure 300 manufactured in accordance with the principles of the present invention is illustrated and described in detail. Specifically, the shield 300 incorporates similar features as the embodiment illustrated in FIG. 1A; i.e., the shield 300 comprises side walls 344, open-top construction 346 and standoffs 342. In addition, the embodiment of FIG. 3 further comprises a plurality of conductive coating contact features 348. These features 348 comprise deflectable contacts which upwardly project out of the open top. These features 348 are adapted so as to engage a top surface of a mold when the internal shield 300 is to be over molded. Since these features 348 are in contact with the top surface of a mold during the over molding process, the tops of these features 348 remain exposed after over molding. This permits contact with the conductive coating that is subsequently disposed on the top surface of the over molding, thereby obviating a dicing step as the contacts are already exposed.

### Methods of Manufacture and Use

Exemplary methods of manufacture and use of the shield apparatus of the present invention are now described in detail. It will be appreciated that while described primarily in terms of one or more of the structural embodiments disclosed herein, and an electroforming process, the methodologies described below may be readily generalized and abstracted to other embodiments by those of ordinary skill.

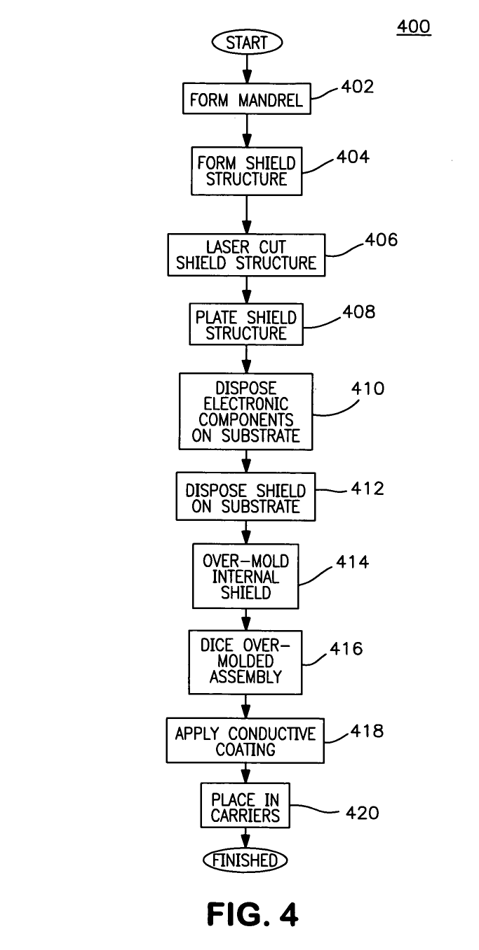

Referring now to FIG. 4, a first exemplary method of manufacturing 400 and using a low-profile electromagnetic shield assembly is shown and described. At step 402, the mandrel utilized in the manufacture of the shield structure is made. The mandrel in one embodiment comprises a re-useable mandrel so that once manufactured, it can be reused to make multiple internal shield structures. The mandrel will advantageously be made using precision machining techniques such as “hard” milling or the like as previously described. The mandrel can be masked or otherwise demarcated in appropriate places to define the boundaries for the electroformed structure.

At step 404, the internal shield structure is formed using, for example, an electroforming process as previously described herein. This electroforming process includes, e.g., an electro-deposition in a plating bath. In one embodiment, the shield structures are electroformed as an array arranged in row-and-column fashion.

At step 406, features in the electroformed internal shields are cutout using laser technology as described previously above. These features include, in one embodiment, the open-top and standoffs of the internal shield. Where required, the shield may be removed from the mandrel before such laser-cutting is performed.

At step 408, the electroformed internal shield structure is optionally plated to improve noise attenuating performance and/or increase the solder-ability of the shield structure (or even for aesthetic reasons).

At step 410, one or more electronic component(s) are placed on a substrate.

At step 412, the electroformed internal shield structure is disposed on the substrate such that the shield at least partly encloses the electronic component(s) and is subsequently connected to one or more grounding pads on the substrate. In one embodiment, the internal shield is conductively adhered or soldered to the grounding pads in a mass termination process that also secures the electronic component(s) to the substrate.

At step 414, the electroformed internal shield structure is partially or completely over-molded with a non-conductive material which also encapsulates the electronic component(s).

At step 416, the encapsulated internal shield structure is subjected to a dicing saw or other operation which exposes the internal shield structure that has been encapsulated.

At step 418, a conductive coating is applied to the encapsulated internal shield structure thereby making contact with the exposed portions of the internal shield.

At optional step 420, the individual assemblies are diced or separated and placed in carriers so that they can subsequently be automatically pick-and-placed by an OEM manufacturer or other end customer of the device.

In another aspect of the invention, a method of creating standoffs is disclosed. In one embodiment, this method comprises creating standoffs by laser-cutting or otherwise perforating a castellated structure (such as a castellated shield structure of the type shown in FIG. 3, for example) disposed between devices. The castellations when diced create intermittent standoffs in the desired locations. In one embodiment, a vertical cut is used for this process, although it will also be recognized that oblique angles may be used as well depending on the dimensions involved and the particular structure utilized. This approach advantageously allows for very fast cuts, since no changes in direction are required (i.e., a “straight” cut is faster than one where direction must be changed).

### Carrier

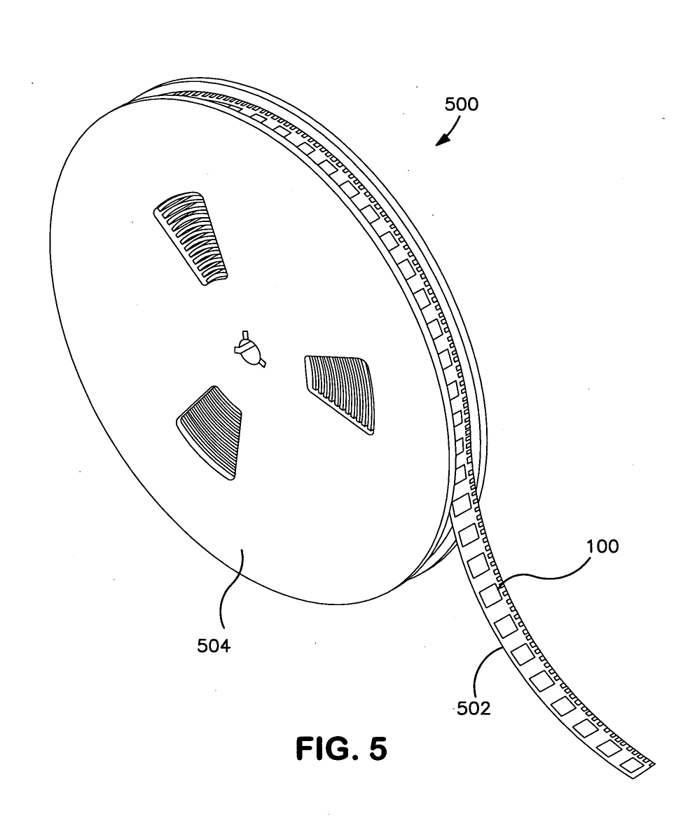

Referring now to FIG. 5, a vacuum formed carrier with adhesives on a carrier reel 500 carrying a plurality of completed shield assemblies 100 such as those shown in FIG. 1 is shown and described in detail. The carrier reel is useful for, inter alia, the automated placement of the shield assemblies 100 onto the parent substrate onto which they will be ultimately mounted. The carrier reel of this embodiment is generally similar to those ubiquitous in the electronics industry, and comprises a polymer carrier 502 wound about a polymer or fibrous (i.e. paper) reel 504. The shield assemblies reside, in one embodiment, within cavities of the carrier and are removed from the cavities via a nozzle or other implement which utilizes a vacuum pressure to remove the structures, and then subsequently place them with a relatively high degree of accuracy.

Other packaging methods such as those disclosed in co-owned U.S. Pat. No. 5,706,952 entitled “Continuous carrier for electrical or mechanical components”; co-owned U.S. Pat. No. 5,938,996 entitled “Method for making a continuous carrier for electrical or mechanical components”; and co-owned U.S. Pat. No. 6,202,853 entitled “Secondary processing for electrical or mechanical components molded to continuous carrier supports”, the contents of each of which are incorporated by reference herein in their entirety, may advantageously be utilized in conjunction with the shield assemblies, internal shield structures or shield structure arrays of the present invention.

### Methods of Designing

As previously noted, it is highly desirable to use a shielding solution that is disposed on the electrically active chips within an electronic device, thereby eliminating the need for the device manufacturer to explicitly consider shielding in the design and construction of their product. This is especially critical for small form-factor devices such as “smartphones” with multiple wireless air interfaces (e.g., Bluetooth, cellular, and WiFi/WiMAX) or potential noise sources, since the inclusion of device- or system-level shielding solution may: (i) require additional space within the already crowded device to implement; and/or (ii) may not provide the best possible shielding performance even when implemented.

By shielding only the components that need to be shielded, and doing so in a “local” or spatially proximate manner, the resulting device design can be simpler, more compact, potentially less costly, and have a higher performance (in terms of reduction of noise or interference to critical device components). Advantageously, the exemplary embodiments of the present invention add very little height or footprint (substrate coverage) to the base electronic component, thereby permitting cost- and space-effective shielding of only particular components that require it.

They also to a large degree untie the hands of the designer in terms of placement of their ICs or other components on the parent substrate (e.g., motherboard), since potentially interfering components (whether “one-way”—i.e., a first component affects a second, but the second does not affect the first, or “two-way”—i.e., mutual interference) can now be placed literally side-by-side on the board and one or both devices shielded. Under typical prior art approaches, one way of preventing such interference was simply to move the two components far enough apart so that the noise intensity/isolation was sufficient to provide an acceptable level of performance. This technique has obvious disabilities in the context of increasingly small form-factor devices.

It will be recognized that while certain aspects of the invention are described in terms of specific design examples, these descriptions are only illustrative of the broader methods of the invention, and may be modified as required by the particular design. Certain steps may be rendered unnecessary or optional under certain circumstances. Additionally, certain steps or functionality may be added to the disclosed embodiments, or the order of performance of two or more steps permuted. All such variations are considered to be encompassed within the invention disclosed and claimed herein.

While the above detailed description has shown, described, and pointed out novel features of the invention as applied to various embodiments, it will be understood that various omissions, substitutions, and changes in the form and details of the device or process illustrated may be made by those skilled in the art without departing from the invention. The foregoing description is of the best mode presently contemplated of carrying out the invention. This description is in no way meant to be limiting, but rather should be taken as illustrative of the general principles of the invention. The scope of the invention should be determined with reference to the claims.

What is claimed is:

1. A shielding assembly, comprising:
a top wall comprising an over-molded polymer with a conductive coating applied thereto; and
a side wall disposed substantially around at least a portion of the periphery of said top wall;
wherein said shielding assembly further comprises a metallic structure that has been formed at least in part using a metal deposition process, and subsequently at least partially encapsulated by said over-molded polymer, said conductive coating being in contact with at least a portion of said metallic structure.

2. The shielding assembly of claim 1, wherein said metal deposition process comprises an electroforming process, and the thickness of said side wall and said plurality of standoff features is less than or equal to 0.10 mm.

3. The shielding assembly of claim 1, wherein said metal deposition process comprises an electroforming process, and the thickness of said top wall is less than or equal to 0.10 mm.

4. The shielding assembly of claim 1, wherein said metallic structure further comprises at least one encapsulant fill aperture.

5. The shielding assembly of claim 4, wherein said at least one aperture is formed within at least a top surface of said metallic structure.

6. The shielding assembly of claim 1, wherein said side wall comprises one or more flange portions adapted to add rigidity to at least said side wall.

7. The shielding assembly of claim 1, wherein said side wall comprises one or more I-beam structures adapted to control stress within at least a portion of said shield assembly.

8. A shielding assembly useful in the attenuation of electronic signals, comprising:
a metallic structure comprising:
a plurality of side walls; and
a plurality of standoff features;
a non-conductive polymer body comprising a top surface and at least partly encapsulating said metallic structure; and
a conductive coating disposed on said top surface, said conductive coating electrically coupled to at least a portion of said metallic structure.

9. The shielding assembly of claim 8, wherein said metallic structure is formed using an electroforming process, and wherein the thickness of said plurality of side walls and said plurality of standoff features is less than or equal to 0.10 mm.

10. The shielding assembly of claim 8, wherein said metallic structure further comprises at least one fill aperture formed at least in a top surface of said metallic structure.

11. The shielding assembly of claim 8, wherein said shield assembly is adapted to at least partly receive two or more discrete electronic devices.

12. The shielding assembly of claim 11, further comprising a substrate, said two or more discrete electronic devices and metallic structure coupled to said substrate.

13. The shielding assembly of claim 12, wherein said conductive coating is electrically coupled to said substrate via said metallic structure.

14. The shielding assembly of claim 13, wherein said conductive coating is coupled to at least a portion of said metallic structure on a top surface of said shielding assembly.

15. A shielding apparatus for attenuating electronic signals or noise, comprising:
a top wall comprising a fill aperture; and
at least one side wall;
wherein said shielding apparatus comprises an electroformed metallic structure, with a plurality of features produced using a process comprising laser-cutting of at least portions of said structure.

16. The shielding apparatus of claim 15, wherein the thickness of at least one of said top wall and said at least one sidewall is less than or equal to 0.10 mm, and the top wall comprises a co planarity which varies less than or equal to 0.10 mm.

17. The shielding apparatus of claim 15, wherein said top wall further comprises at least one structure which projects into said aperture, said at least one structure used for making electrical contact with a conductive layer.

18. A method of manufacturing a shield assembly, said shield assembly comprising a shield apparatus, a top wall, and a sidewall disposed substantially about at least a portion of the periphery of said top wall, said method comprising:
providing a mandrel;
depositing, using a metal deposition process, at least a portion of said shield apparatus on areas of said mandrel; and
laser-cutting at least a portion of said shield apparatus.

19. The method of claim 18, further comprising removing said at least portions of said shield apparatus from said mandrel before said laser-cutting is performed.

20. The method of claim 19, further comprising placing said shield assembly in a carrier.

21. The method of claim 18, wherein said shield assembly is part of an array of shield assemblies, and said act of depositing comprises electroforming each shield apparatus of said array of shield assemblies substantially simultaneously.

22. The method of claim 18, further comprising encapsulating at least a portion of said shield apparatus to form at least a portion of said top wall and sidewall.

23. The method of claim 22, further comprising cutting at least a portion of said encapsulated shield assembly, thereby exposing at least a portion of said shield apparatus.

24. The method of claim 23, further comprising depositing a conductive layer on said top wall, said conductive layer contacting with said exposed portion of said shield apparatus.

25. A shielded electronic assembly, comprising:
a substrate;
at least one electronic component disposed directly or indirectly on said substrate;
a substantially metallic electroformed shield component substantially surrounding said at least one electronic component, said shield component being in electrical contact with at least one conductive area on said substrate;
an encapsulant substantially covering at least portions of said at least one electronic component and said shield component; and
a conductive layer disposed atop at least a portion of said encapsulant, said conductive layer being in electrical contact with said shield component.

26. The assembly of claim 25, wherein said at least one electronic component comprises at least one integrated circuit (IC).

27. The assembly of claim 25, wherein said shield component comprises a sidewall portion having a plurality of standoffs, and a top portion having an aperture formed therein.

28. The assembly of claim 25, wherein at least portions of said shield component are less than or equal to 0.002 in. thick.

29. A shield component useful in shielding electronic noise, said component comprising a top wall and a sidewall disposed substantially about at least a portion of the periphery of said top wall, said component manufactured according to the method comprising:
depositing, using a wet metal deposition process, one or more layers of a shield material on areas of said mandrel to form said shield component; and
laser-cutting at least a portion of said shield component;
wherein at least portions of said shield component are less than or equal to 0.002 in. thick.

30. A low-profile shielded electronic assembly, comprising:
a substrate;
at least one electronic component disposed directly or indirectly on said substrate;
a substantially metallic electroformed shield component substantially surrounding said at least one electronic component, said shield component being in electrical contact with at least one conductive area on said substrate;
an encapsulant substantially covering at least portions of said at least one electronic component and said shield component; and
a conductive layer disposed atop at least a portion of said encapsulant, said conductive layer being in electrical contact with said shield component;
wherein said conductive layer and said encapsulant are the only components disposed over the majority of the top surface area of the at least one electronic component.

31. A method of designing a shielded electronic device, the method comprising:
including at least one electronic component within said design;
locally shielding said at least one electronic component, said local shielding comprising disposing a substantially adherent shield assembly comprised of an electroformed shield component and a conductive layer in communication therewith substantially about said at least one electronic component; and
not including additional shielding relating to said at least one component elsewhere within said design of said device.
